(19) United States
(12) Patent Application Publication
(10) Pub. No.: US 2015/0255553 A1
(43) Pub. Date: Sep. 10, 2015

(54) SEMICONDUCTOR DEVICE AND METHOD OF MANUFACTURING THE SAME

(71) Applicant: PS5 Luxco S.a.r.L., Luxembourg (LU)

(72) Inventor: Kazunori Niitsuma, Tokyo (JP)

(21) Appl. No.: 14/430,832

(22) PCT Filed: Sep. 12, 2013
(86) PCT No.: PCT/JP2013/074676

§ 371 Date: Mar. 24, 2015

(30) Foreign Application Priority Data
Sep. 26, 2012 (JP) 2012-212802

(51) Int. Cl. H01L 29/423; H01L 21/28; H01L 27/108; H01L 21/306; H01L 29/78; H01L 29/66

(52) U.S. Cl. CPC H01L 29/4236; H01L 29/78; H01L 29/66621; H01L 27/10823; H01L 27/10876; H01L 29/42364; H01L 29/42372; H01L 21/30604; H01L 21/28017

(57) ABSTRACT

A semiconductor device having a groove provided in a semiconductor substrate, a gate insulating film provided so as to cover an inside surface of the groove, a first conductive film provided inside the groove in a position in which a first upper end surface is lower than the outer surface of the semiconductor substrate, a second conductive film provided inside the groove in a position that protrudes beyond the first upper end surface and in which a second upper end surface is higher than the outer surface of the semiconductor substrate, and a cap insulating film provided inside the groove so as to cover a protruding part of the second conductive film that protrudes beyond the first upper end surface.

### TECHNICAL FIELD

The present invention relates to a semiconductor device and a method for manufacturing the same.

### BACKGROUND ART

There are MOS (Metal Oxide Semiconductor) transistors comprising a groove formed in a semiconductor substrate, a gate insulating film formed in the groove, a gate electrode (embedded gate electrode) provided in the groove, an insulating film which fills the groove in which the gate electrode has been formed, in such a way that said insulating film reaches the surface of the semiconductor substrate, a first impurity-diffused layer formed in the semiconductor substrate and disposed on one side of the groove, and a second impurity-diffused layer formed in the semiconductor substrate and disposed on the other side of the groove.

In this MOS transistor, in a state in which a drain voltage is applied to one of the impurity-diffused layers, which functions as the drain region, and the other impurity-diffused layer, which functions as the source region, is set to a source voltage, if an ON potential is imparted to the gate electrode, a channel region is formed in the sidewalls and the bottom portion of the groove, and the MOS transistor operates.

However, problems such as those described below arise if one attempts to achieve threshold voltage control and a reduction in the gate electrode resistance by forming an embedded gate electrode using a first conductive film, in contact with the gate insulating film, and a second conductive film having a reduced resistance.

To elaborate, if the gate electrode (word line) is formed by etching the first and second conductive films together, variability arises in the etching speed due to the effects of crystal grain boundaries formed in the second conductive film, which is thicker than the first conductive film, and irregularities form in the surface (etched surface) of the gate electrode.

Thus in the gate electrode there are inevitably sections which face the side surface of the first impurity-diffused layer, and sections which do not face the side surface of the first impurity-diffused layer, and because the electric field intensity increases in the sections which face the side surface of the first impurity-diffused layer, GIDL (Gate-Induced Drain Leakage) also increases.

The information retention characteristic, which is a critical characteristic of DRAMs, deteriorates as the junction leakage current in the depletion layer formed between the semiconductor substrate and the first impurity-diffused layer, which is electrically connected to the lower electrode of a capacitor, increases, this junction leakage current arising largely due to GIDL influenced by the gate electric field.

Thus, if the location of the junction between the first impurity-diffused layer and the semiconductor substrate is deeper than the surface of the gate electrode, there is a problem in that GIDL influenced by the gate electric field cannot be ignored.

In order to resolve such problems, in Japanese Patent Kokai 2011-233582 (patent literature article 1), by including an insulating film provided in a recessed portion in such a way as to cover a second conductive film protruding from an upper end surface of a first conductive film, the insulating film disposed in a gap (a gap formed between a gate insulating film and the second conductive film) formed on the upper end surface of the first conductive film functions as part of the gate insulating film, and thus the effective gate insulating film thickness in the region in which GIDL occurs can be increased. This reduces the susceptibility of the device to the effects of the gate electric field, and therefore the GIDL in the depletion layer formed between the impurity-diffused layer and the semiconductor substrate can be suppressed.

### PATENT LITERATURE

Patent literature article 1: Japanese Patent Kokai 2011-233582

### SUMMARY OF THE INVENTION

### Problems to be Resolved by the Invention

However, in the abovementioned patent literature article 1, the location of the second conductive film is lower than the surface of the semiconductor substrate, and there is thus a problem in that the word line wiring resistance increases.

The present invention provides a semiconductor device with which GIDL can be suppressed and with which increases in the word line wiring resistance can also be suppressed, and a method for manufacturing the same.

### Means of Overcoming the Problems

A semiconductor device according to one mode of embodiment of the present invention is characterized in that it comprises:

a groove provided in a semiconductor substrate;
a gate insulating film provided in such a way as to cover the inner surfaces of the groove;
inside the groove, a first conductive film, of which a first upper end surface is provided in a location that is lower than the surface of the semiconductor substrate; inside the groove, a second conductive film which protrudes from the first upper end surface, and of which a second upper end surface is provided in a location that is higher than the surface of the semiconductor substrate; and
a cap insulating film provided in the groove in such a way as to cover the protruding portion of the second conductive film that protrudes from the first upper end surface.

Further, a method of manufacturing a semiconductor device according to one mode of embodiment of the present invention is characterized in that it comprises:

etching a semiconductor substrate to form a groove in the semiconductor substrate; forming a gate insulating film in such a way as to cover the inner surfaces of the groove;
forming a first conductive film inside the groove in such a way that a first upper end surface of said first conductive film is disposed in a location that is lower than the surface of the semiconductor substrate;
forming a second conductive film inside the groove in such a way that it protrudes from the first upper end surface, and in such a way that a second upper end surface of said second conductive film is disposed in a location that is higher than the surface of the semiconductor substrate; and
forming a cap insulating film in the groove in such a way as to cover the protruding portion of the second conductive film that protrudes from the first upper end surface.

### Advantages of the Invention

According to the present invention, GIDL can be suppressed and increases in the word line wiring resistance can also be suppressed.

### BRIEF EXPLANATION OF THE DRAWINGS

FIG. 1 is a plan view illustrating the structure of a semiconductor device according to a first mode of embodiment of the present invention.

FIG. 2 is a drawing illustrating the structure of the semiconductor device according to the first mode of embodiment of the present invention, being a cross-sectional view along A-A′ in FIG. 1.

FIG. 3 is a cross-sectional view illustrating a process in the manufacture of the semiconductor device according to the first mode of embodiment of the present invention.

FIG. 4 is a cross-sectional view illustrating a process in the manufacture of the semiconductor device according to the first mode of embodiment of the present invention.

FIG. 5 is a cross-sectional view illustrating a process in the manufacture of the semiconductor device according to the first mode of embodiment of the present invention.

FIG. 6 is a cross-sectional view illustrating a process in the manufacture of the semiconductor device according to the first mode of embodiment of the present invention.

FIG. 7 is a cross-sectional view illustrating a process in the manufacture of the semiconductor device according to the first mode of embodiment of the present invention.

FIG. 8 is a cross-sectional view illustrating a process in the manufacture of the semiconductor device according to the first mode of embodiment of the present invention.

FIG. 9 is a cross-sectional view illustrating a process in the manufacture of the semiconductor device according to the first mode of embodiment of the present invention.

FIG. 10 is a cross-sectional view illustrating a process in the manufacture of the semiconductor device according to the first mode of embodiment of the present invention.

FIG. 11 is a plan view illustrating the structure of a semiconductor device according to a second mode of embodiment of the present invention.

FIG. 12 is a drawing illustrating the structure of the semiconductor device according to the second mode of embodiment of the present invention, being a cross-sectional view along A-A′ in FIG. 11.

FIG. 13 is a cross-sectional view illustrating a process in the manufacture of the semiconductor device according to the second mode of embodiment of the present invention.

FIG. 14 is a cross-sectional view illustrating a process in the manufacture of the semiconductor device according to the second mode of embodiment of the present invention.

FIG. 15 is a cross-sectional view illustrating a process in the manufacture of the semiconductor device according to the second mode of embodiment of the present invention.

FIG. 16 is a cross-sectional view illustrating a process in the manufacture of the semiconductor device according to the second mode of embodiment of the present invention.

FIG. 17 is a cross-sectional view illustrating a process in the manufacture of the semiconductor device according to the second mode of embodiment of the present invention.

FIG. 18 is a cross-sectional view illustrating a process in the manufacture of the semiconductor device according to the second mode of embodiment of the present invention.

FIG. 19 is a plan view illustrating the structure of a semiconductor device according to a third mode of embodiment of the present invention.

FIG. 20 is a drawing illustrating the structure of the semiconductor device according to the third mode of embodiment of the present invention, being a cross-sectional view along A-A′ in FIG. 19.

FIG. 21 is a cross-sectional view illustrating a process in the manufacture of the semiconductor device according to the third mode of embodiment of the present invention.

FIG. 22 is a cross-sectional view illustrating a process in the manufacture of the semiconductor device according to the third mode of embodiment of the present invention.

FIG. 23 is a cross-sectional view illustrating a process in the manufacture of the semiconductor device according to the third mode of embodiment of the present invention.

FIG. 24 is a cross-sectional view illustrating a process in the manufacture of the semiconductor device according to the third mode of embodiment of the present invention.

FIG. 25 is a plan view illustrating the structure of a semiconductor device in the related art.

FIG. 26 is a drawing illustrating the structure of the semiconductor device in the related art, being a cross-sectional view along A-A′ in FIG. 25.

### MODES OF EMBODYING THE INVENTION

A semiconductor device according to the related art will first be described in order to clarify the characteristics of the present invention.

### RELATED ART

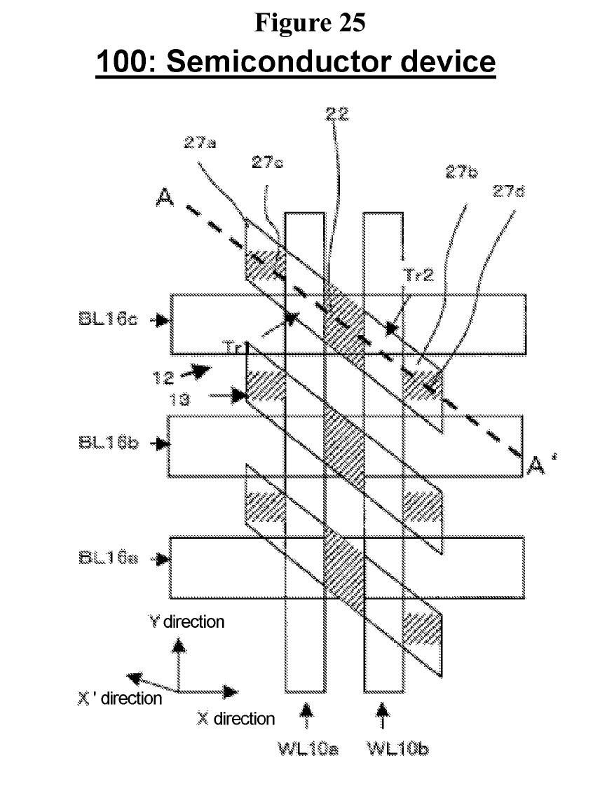

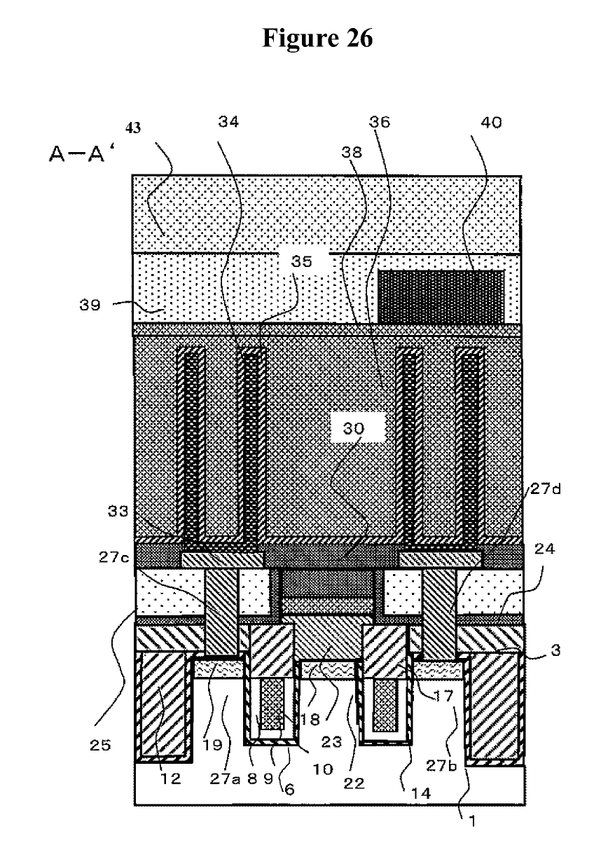

FIG. 25 and FIG. 26 are drawings illustrating the structure of a semiconductor device 100 according to the related art. The semiconductor device 100 according to this embodiment is a DRAM memory cell, FIG. 25 is a plan view and FIG. 26 is a cross-sectional view along A-A′ in FIG. 25.

The semiconductor device 100 in the related art will first be described with reference to the plan view in FIG. 25.

The semiconductor device 100 forms the memory cells of a DRAM. A plurality of element isolation regions 12 extending continuously in the X′-direction, and a plurality of active regions 13, also extending continuously in the X′-direction, are disposed alternately at equal intervals and with an equal pitch in the Y-direction on a semiconductor substrate 1. The element isolation regions 12 are formed by an element isolation insulating film which is embedded in a groove. A first embedded word line (hereinafter referred to as a first word line) WL10a and a second embedded word line (hereinafter referred to as a second word line) WL10b which extend continuously in the Y-direction are disposed straddling the plurality of element isolation regions 12 and the plurality of active regions 13.

The active regions 13 comprise a first capacitative contact region 27a, the first word line WL10a disposed adjacent to the first capacitative contact region 27a, a bit line contact region 22 disposed adjacent to the first word line WL10a, the second word line 10b disposed adjacent to the bit line contact region 22, and a second capacitative contact region 27b disposed adjacent to the second word line WL10b. The first capacitative contact region 27a, the first word line WL10a and the bit line contact region 22 form a first cell transistor Tr1, and the bit line contact region 22, the second word line WL10b and the second capacitative contact region 27c form a second cell transistor Tr2. The memory cell in the related art is formed by disposing a plurality of the abovementioned active regions 13 in the X-direction.

Next, with reference to FIG. 26, grooves 14 for word lines which also serve as the transistor gate electrodes are provided in the semiconductor substrate 1. Gate insulating films 6 are provided in such a way as to cover the inner surfaces of the grooves 14 for the word lines. Word lines 10 are provided in the bottom portion of each groove, with the interposition of the gate insulating films 6.

Cap insulating films 17 are provided covering the word lines and filling the grooves. Further, a first interlayer insulating film 3 is provided in such a way as to cover the silicon substrate 1. Semiconductor pillars located to the outside of the word lines 10 serve as the capacitative contact regions 27, and first impurity-diffused layers 19 which serve as either the source or the drain are provided on the upper surfaces of said semiconductor pillars. A semiconductor pillar located between the word lines 10 serves as the BL contact region 22, and a second impurity-diffused layer 18 which serves as the other of the source or the drain is provided on the upper surface of said semiconductor pillar. The first impurity-diffused layer 19, the gate insulating film 6, the word line WL10 and the second impurity-diffused layer 18 form the transistor Tr1.

The word lines 10 also serve as the gate electrodes, and comprise a first conductive film 8 and a second conductive film 9. The first conductive film 8 is a film which is responsible for determining the threshold voltage of Tr1 and Tr2, and which also functions as a barrier film preventing heavy-metal atoms that are contained in the second conductive film 9 and that would adversely affect the characteristics of the transistor if dispersed in the semiconductor substrate 1, from reaching the gate insulating film 6.

The second conductive film 9 is formed on the first conductive film 8, and is provided in such a way as to fill part of the groove 14 for the word lines, in which the first conductive film 8 has been formed.

In order to reduce its wiring resistance, the second conductive film 9 employs a film having a lower resistance than the first conductive film, it is situated in such a way that it faces portions of the first and second impurity-diffused layers 18 and 19, and its upper end surface is coplanar with the upper end surface of the first conductive film 8.

Further, in the related art, in order to reduce the wiring resistance of the word lines 10, the first impurity-diffused layer 19 and the second impurity-diffused layer 18 are configured relative to the word lines 10 in such a way that the lower end surfaces of the first impurity-diffused layer 19 and the second impurity-diffused layer 18 are coplanar with the upper end surfaces of the word lines 10. The cap insulating films 17 cover the word lines 10, and their surfaces are coplanar with the surface of the first interlayer insulating film 3.

A bit line (BL) 23 connected to the impurity-diffused layer 18 in the BL contact region 22 is provided on the first interlayer insulating film 3. A cover insulating film is provided on the upper surface of the BL 23. A liner insulating film 24 is provided over the entire surface in such a way as to cover the sidewalls of the BL 23. SOD films 25 which fill recessed spaces formed between adjacent BLs are provided on the liner insulating film 24.

Capacitative contact holes 27 are provided penetrating through the SOD films 25 and the liner film 24. Capacitative contact plugs 27c and 27d are connected to the capacitative contact regions 27a and 27b respectively by way of the capacitative contact holes 27. Capacitative contact pads 33 are connected to the upper portions of the capacitative contact plugs 27c and 27d. Capacitor lower electrodes 34 are provided on the capacitative contact pads 33. A capacitative insulating film 35 is provided covering the inner surfaces of the lower electrodes 34, and an upper polysilicon electrode 36 and an upper tungsten electrode 38 are provided on the capacitative insulating film 35, thereby forming a capacitor.

A second interlayer insulating film 39 is then formed on the tungsten upper electrode 38. Wiring lines 40 of aluminum or the like are also formed on the second interlayer insulating film 39. A surface protection film 41 is then formed, thereby forming the semiconductor device 100.

In the related art described above, in order to reduce the wiring resistance of the word lines 10, the first impurity-diffused layer 19 and the second impurity-diffused layer 18 are configured relative to the word lines 10 in such a way that the lower end surfaces of the first impurity-diffused layer 19 and the second impurity-diffused layer 18 are coplanar with the upper end surfaces of the word lines 10. There is thus a problem in that the junction field of the transistor becomes stronger, causing the refresh characteristics to deteriorate.

The objective of the present invention is to resolve the problems in the abovementioned related art, and it provides a semiconductor device with which it is possible to improve the refresh characteristics by suppressing GIDL in order to reduce the junction field of the transistor, and with which it is also possible to suppress increases in the word line wiring resistance, and a method for manufacturing the same.

### Modes of Embodying the Present Invention

Preferred modes of embodiment of the present invention will now be described in detail with reference to the drawings.

### First Mode of Embodiment

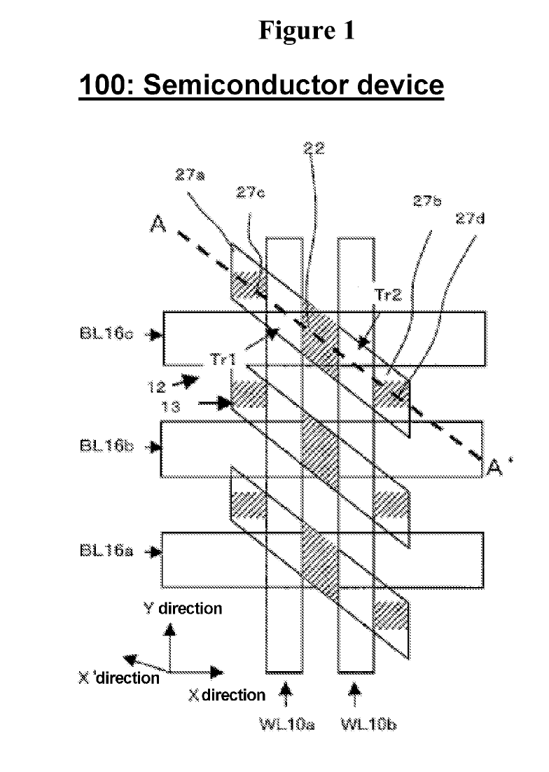

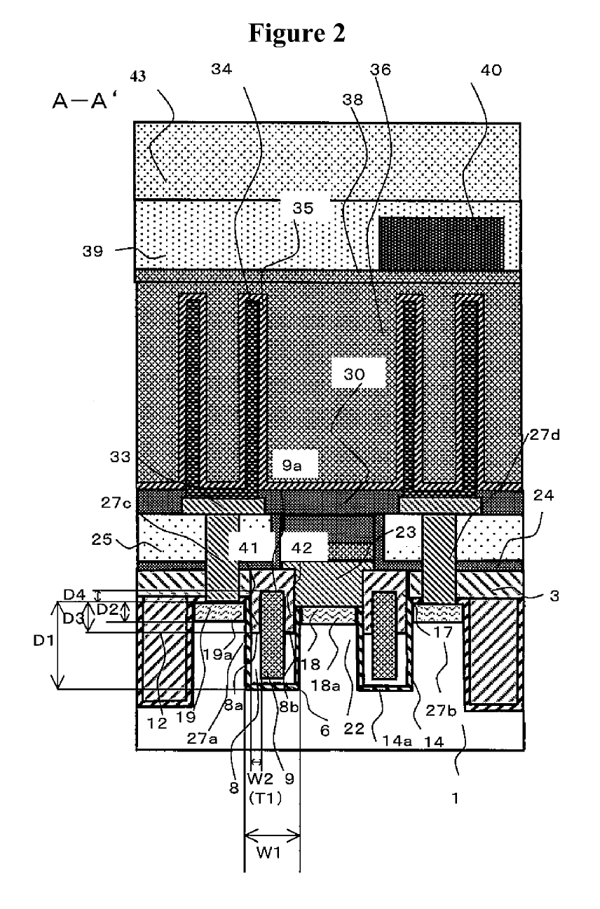

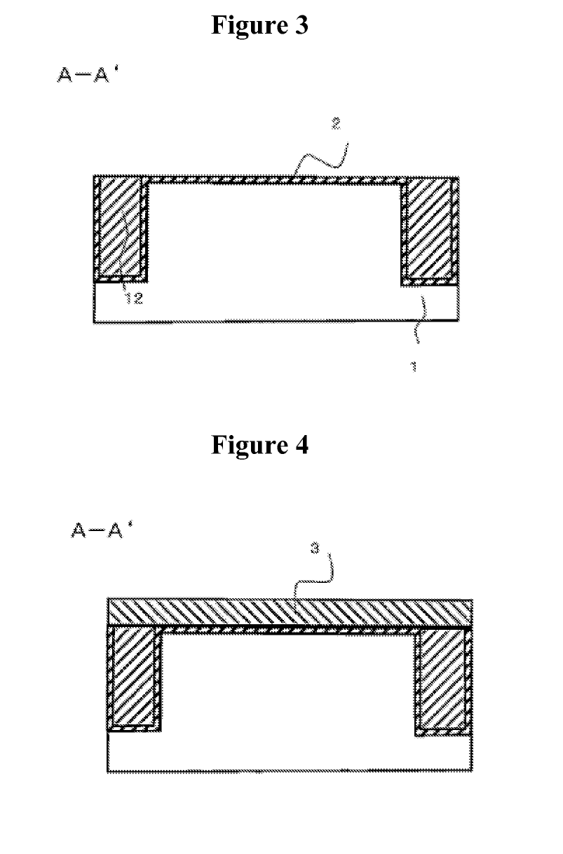

FIG. 1 to FIG. 10 are drawings illustrating the structure of a semiconductor device 100 according to a first preferred mode of embodiment of the present invention. The semiconductor device 100 according to this first mode of embodiment is a DRAM memory cell, FIG. 1 is a plan view, FIG. 2 is a cross-sectional view along A-A′ in FIG. 1, and FIG. 3 to FIG. 10 are a series of cross-sectional views in a manufacturing process.

The semiconductor device 100 in the first mode of embodiment will first be described with reference to the plan view in FIG. 1.

The semiconductor device 100 forms the memory cells of a DRAM. A plurality of element isolation regions 12 extending continuously in the X′-direction, and a plurality of active regions 13, also extending continuously in the X′-direction, are disposed alternately at equal intervals and with an equal pitch in the Y-direction on a semiconductor substrate 1. The element isolation regions 12 are formed by an element isolation insulating film which is embedded in a groove. A first embedded word line (hereinafter referred to as a first word line) WL10a and a second embedded word line (hereinafter referred to as a second word line) WL10b which extend continuously in the Y-direction are disposed straddling the plurality of element isolation regions 12 and the plurality of active regions 13.

The active regions 13 comprise a first capacitative contact region 27a, the first word line WL10a disposed adjacent to the first capacitative contact region 27a, a bit line contact region 22 disposed adjacent to the first word line WL10a, the second word line 10b disposed adjacent to the bit line contact region 22, and a second capacitative contact region 27b disposed adjacent to the second word line WL10b. The first capacitative contact region 27a, the first word line WL10a and the bit line contact region 22 form a first cell transistor Tr1, and the bit line contact region 22, the second word line WL10b and the second capacitative contact region 27c form a second cell transistor Tr2.

The memory cell in the first mode of embodiment of the present invention is formed by disposing a plurality of the abovementioned active regions 13 in the X-direction.

Next, with reference to FIG. 2, grooves 14 for word lines which also serve as the transistor gate electrodes are provided in the semiconductor substrate 1. The depth D1 of the grooves relative to the surface of the semiconductor substrate 1 can for example be set to 120 nm.

Gate insulating films 6 are provided in such a way as to cover the inner surfaces of the grooves 14 for the word lines. Word lines 10 are provided in the bottom portion of each groove, with the interposition of the gate insulating films 6.

Cap insulating films 17 are provided covering the word lines and filling the grooves. Further, a first interlayer insulating film 3 is provided in such a way as to cover the silicon substrate 1. Semiconductor pillars located to the outside of the word lines 10 serve as the capacitative contact regions 27, and first impurity-diffused layers 19 which serve as either the source or the drain are provided on the upper surfaces of said semiconductor pillars. A semiconductor pillar located between the word lines 10 serves as the BL contact region 22, and a second impurity-diffused layer 18 which serves as the other of the source or the drain is provided on the upper surface of said semiconductor pillar. The first impurity-diffused layer 19, the gate insulating film 6, the word line WL10 and the second impurity-diffused layer 18 form the transistor Tr1.

Here, the depth of the first impurity-diffused layer 19 and the depth of the second impurity-diffused layer 18 from the surface of the semiconductor substrate 1 are the same, and this depth D2 can for example be set to 40 nm.

The word lines 10 also serve as the gate electrodes, and comprise a first conductive film 8 and a second conductive film 9. The first conductive film 8 is a film which is responsible for determining the threshold voltage of Tr1 and Tr2, and which also functions as a barrier film preventing heavy-metal atoms that are contained in the second conductive film 9 and that would adversely affect the characteristics of the transistor if dispersed in the semiconductor substrate 1, from reaching the gate insulating film 6.

The first conductive films 8 have etched upper end surfaces 8a and 8b. Relative to lower end surfaces 19a of the first impurity-diffused layers 19, the upper end surfaces 8a of the first conductive films 8 are disposed further toward a bottom surface 14a of the grooves 14 for the word lines. Similarly, relative to a lower end surface 18a of the second impurity-diffused layer 18, the second upper end surfaces 8b of the first conductive films 8 are disposed further toward the bottom surface 14a of the grooves 14 for the word lines.

The depths from the surface of the semiconductor substrate 1 to the upper end surfaces 8a and 8b of the first conductive films 8 are the same, and this depth D3 can for example be set to 50 nm.

If a titanium nitride film is used as the first conductive film 8, its thickness can for example be set to 5 nm. In order to reduce the wiring resistance of the word line 10, the second conductive film 9 is formed on the first conductive film 8, and is provided in such a way as to fill part of the groove 14 for the word lines, in which the first conductive film 8 has been formed.

The second conductive film 9 protrudes from the upper end surfaces 8a and 8b of the first conductive film 8 in such a way that it faces portions of the first and second impurity-diffused layers 18 and 19. By this means, a gap 41 extending in the Y-direction and surrounded by the upper end surface 8a of the first conductive film 8, the second conductive film 9 and the gate insulating film 6 is formed above the upper end surface 8a of the first conductive film 8, and similarly a gap 42 extending in the Y-direction and surrounded by the upper end surface 8b of the first conductive film 8, the second conductive film 9 and the gate insulating film 6 is formed above the upper end surface 8b of the first conductive film 8.

The width of the gap 42 is equal to the width W2 of the gap 41, and the width of the gap 41 is equal to the thickness of the first conductive film 8. If the thickness of the first conductive film 8 is 5 nm, the width W2 of the gap 41 can be set to 5 nm.

The upper end surface 9a of the second conductive film 9 is disposed between the surface of the semiconductor substrate 1 and the surface of the first interlayer insulating film 3. The height D4 to the upper end surface 9a of the second conductive film 9 relative to the surface of the semiconductor substrate 1 can for example be set to 5 nm. The resistance of the word line 10 can be reduced by increasing the height to the upper end surface.

The cap insulating films 17 are provided in such a way as to fill the gaps 41 and 42, but the gaps need not necessarily be completely filled.

Further, the cap insulating films 17 cover the second conductive films 9 which protrude from the surface of the semiconductor substrate 1, and the surfaces of the cap insulating films 17 are coplanar with the surface of the first interlayer insulating film 3. The thickness T1 of the cap insulating film 17 formed in the gap 41 is equal to the width W2 of the gap 41.

A bit line (BL) 23 connected to the impurity-diffused layer 18 in the BL contact region 22 is provided on the first interlayer insulating film 3. A cover insulating film is provided on the upper surface of the BL 23. A liner insulating film 24 is provided over the entire surface in such a way as to cover the sidewalls of the BL 23. SOD films 25 which fill recessed spaces formed between adjacent BLs are provided on the liner insulating film 24.

Capacitative contact holes 27 are provided penetrating through the SOD films 25 and the liner film 24. Capacitative contact plugs 27c and 27d are connected to the capacitative contact regions 27a and 27b respectively by way of the capacitative contact holes 27. Capacitative contact pads 33 are connected to the upper portions of the capacitative contact plugs 27c and 27d. Capacitor lower electrodes 34 are provided on the capacitative contact pads 33. A capacitative insulating film 35 is provided covering the inner surfaces of the lower electrodes 34, and an upper polysilicon electrode 36 and an upper tungsten electrode 38 are provided on the capacitative insulating film 35, thereby forming a capacitor.

A second interlayer insulating film 39 is then formed on the tungsten upper electrode 38. Wiring lines 40 of aluminum or the like are also formed on the second interlayer insulating film 39. A surface protection film 41 is then formed, thereby forming the semiconductor device 100.

In the semiconductor device 100, the cap insulating film 17 is provided in the groove 14 for the word lines in such a way as to cover the second conductive film 9 which protrudes from the upper end surface 8a and the upper end surface 8b of the first conductive film 8, and the upper end surface 9a of which is located higher than the surface of the semiconductor substrate 1, and thus the cap insulating film 17 functions as part of the gate insulating film 6 located on the upper end surface 8a of the first conductive film 8, and therefore the thickness of the gate insulating film in the region in which GIDL (Gate-Induced Drain Leakage) occurs can be increased, the junction field of the transistor can be reduced, and the refresh characteristics can be improved.

Moreover, by setting the location of the upper end surface 9a of the second conductive film 9 to a location that is higher than the surface of the semiconductor substrate 1, the wiring resistance of the second conductive film 9 can be maintained.

A method of manufacturing the semiconductor device 100 illustrated in FIG. 1 and FIG. 2 will now be described with reference to FIG. 3 to FIG. 9. FIG. 3 to FIG. 8 are cross-sectional views along A-A′ in FIG. 1.

First, as illustrated in FIG. 3, a pad oxide film 2 is formed on the semiconductor substrate 1, and the element isolation regions 12, filled using an insulating film comprising a silicon dioxide film, are formed using a known STI method.

Next, as illustrated in FIG. 4, the first interlayer insulating film 3 is formed on the pad oxide film 2 using a silicon dioxide film, for example.

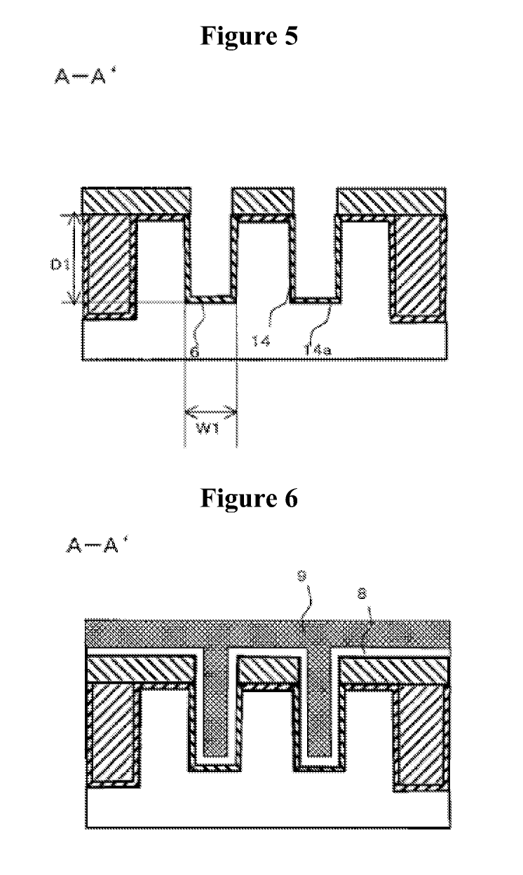

Next, as illustrated in FIG. 5, the semiconductor substrate 1 is etched by dry etching using the first interlayer insulating film 3 as a mask to form the grooves 14 for the word lines.

The depth D1 of the grooves 14 for the word lines can for example be set to 120 nm. Further, the width W1 of the grooves 14 for the word lines can for example be set to 50 nm.

Then the gate insulating film 6 which is a constituent of an n-type transistor is formed on the active region 13 of the silicon substrate 1 using a thermal oxidation process.

Next, as illustrated in FIG. 6, the first conductive film 8 comprising titanium nitride or the like is deposited by CVD to a thickness of 5 nm in such a way as to cover the surfaces of the gate insulating film 6 and the first interlayer insulating film 3.

Next, the second conductive film 9 comprising tungsten or the like is deposited by CVD onto the surface of the first conductive film 8 to a thickness of 30 nm in such a way as to fill the grooves 14 for the word lines.

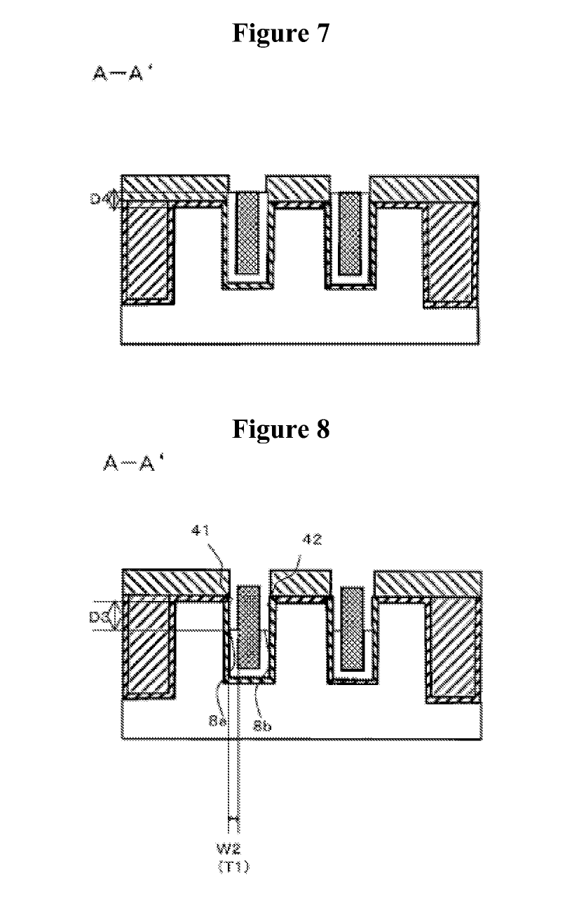

Next, as illustrated in FIG. 7, the first conductive film 8 and the second conductive film 9 are etched back to a location that is higher than the surface of the semiconductor substrate 1 and is lower than the surface of the first interlayer insulating film 3.

Here, the height D4 of the second conductive film 9 from the semiconductor substrate can for example be set to 5 nm.

Next, as illustrated in FIG. 8, the upper end portions of the first conductive films 8 are selectively wet-etched using a mixture of hydrofluoric acid and a hydrogen peroxide solution, in such a way that, relative to the lower end portions of the first impurity-diffused layers 19 and the second impurity-diffused layer 18, the locations of the upper end portions 8a and 8b of the first conductive films 8 are disposed further toward the bottom surface 14a of the grooves 14 for the word lines.

By this means, the gap 41 surrounded by the upper end portion 8a of the first conductive film 8, the second conductive film 9 and the gate insulating film 6 is formed above the upper end portion 8a of the first conductive film 8, and the gap 42 surrounded by the upper end portion 8b of the first conductive film 8, the second conductive film 9 and the gate insulating film 6 is formed above the upper end portion 8b of the first conductive film 8.

The width W2 of the gap 41 is equal to the thickness of the first conductive film 8, and can for example be set to 5 nm. The width of the gap 42 is equal to W2.

Further, the upper end surface 8b and the upper end surface 8a are made coplanar by the wet etching. Here, the depth D3 of the upper end surfaces 8a and 8b relative to the surface of the semiconductor substrate 1 can for example be set to 50 nm.

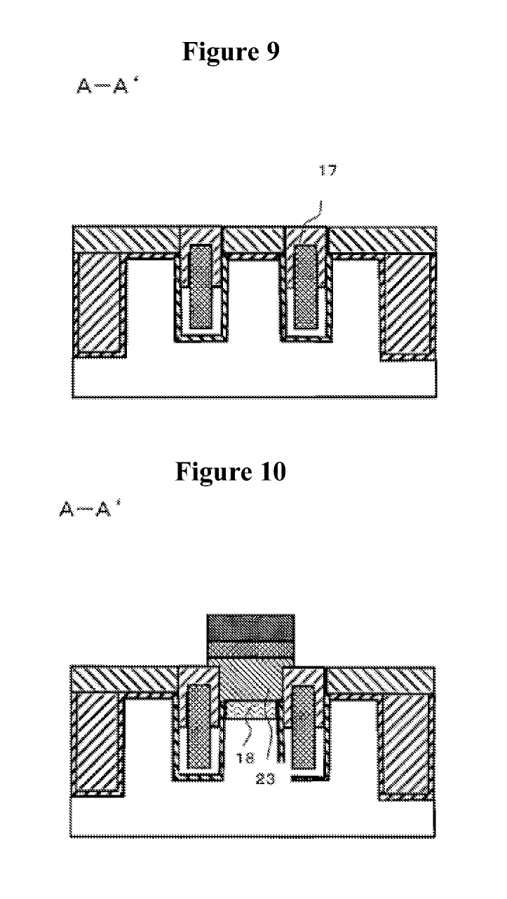

Next, as illustrated in FIG. 9, the cap insulating films 17 (for example silicon nitride films having a thickness of 50 nm) are deposited in such a way as to fill the gaps 41 and 42, after which the cap insulating films 17 are etched back such that they become flush with the surface of the first interlayer insulating film 3. The thickness T1 of the cap insulating films formed in the gaps 41 and 42 is equal to the thickness of the first conductive film 8. T1 can for example be set to 5 nm.

By filling the gap 41 using the cap insulating film 17 in this way, the cap insulating film 17 with which the gap 41 has been filled functions as part of the gate insulating film 17, and therefore the effective gate insulating film thickness in the region in which GIDL influenced by the gate electric field occurs can be increased. This reduces the susceptibility of the device to the effects of the gate electric field, and therefore the GIDL in the depletion layer formed between the first impurity-diffused layer 19 and the semiconductor substrate 1 can be suppressed.

Therefore, if the semiconductor device 100 in the first mode of embodiment of the present invention is used as a DRAM, it is possible to suppress deterioration of the information retention characteristic attributable to GIDL influenced by the gate electric field. Moreover, by disposing the upper end surface 9a of the second conductive film 9 in a location that is higher than the surface of the semiconductor substrate 1, increases in the wiring resistance of the word lines 10 can also be suppressed.

Next, as illustrated in FIG. 10, a portion of the first interlayer insulating film 3 is removed by photolithography and dry etching, to form a bit contact connected to the upper surface of the bit contact region 22. The bit contact is formed as an open pattern in the shape of a line extending in the same direction (the Y-direction in FIG. 1) as the word lines 10. The surface of the semiconductor substrate 1 is exposed in the areas in which the bit contact pattern and the active regions intersect.

After the bit contact has been formed, an n-type impurity (arsenic or the like) is ion-implanted to form the second impurity-diffused layer 18 in the vicinity of the surface of the silicon. The second impurity-diffused region which has been formed functions as the source region or the drain region of the transistor. A laminated film comprising a polysilicon film, a tungsten film and a silicon nitride film, for example, is then formed by CVD. This is then patterned into the shape of a line by photolithography and dry etching to form the bit line 23. The bit line 23 is formed as a pattern extending in a direction (the X-direction in FIG. 1) that intersects the word lines 10. The polysilicon film which forms the lower layer of the bit line 23 is connected to the second impurity-diffused layer 18 in the sections of the silicon surface that are exposed within the bit contact.

Next, as illustrated in FIG. 2, a silicon nitride film is formed covering the side surfaces of the bit line, after which the liner film 24 covering the upper surface thereof is formed using a silicon nitride film, for example, by CVD or the like.

The SOD films 25, which are coating films, are deposited in such a way as to fill the spaces between the bit lines, after which an annealing process is performed in a high-temperature steam (H₂O) atmosphere to reform the SOD films to a solid film. Planarization is performed by CMP until the upper surface of the liner film 24 is exposed.

The capacitative contacts 27 are then formed by employing photolithography and dry etching to penetrate through the SOD films 25 and the liner film 24. Further, an n-type impurity (arsenic or the like) is ion-implanted in the vicinity of the surface in the capacitative contact regions 27a and 27b to form the first impurity-diffused layers 19 in the vicinity of the surface of the silicon. The first impurity-diffused regions 19 which have been formed function as the source region or the drain region of the transistor.

Next, the insides of the capacitative contacts 27 are filled using tungsten or the like to form the capacitative contact plugs 27c and 27d.

A wiring-line material layer comprising titanium nitride, tungsten or the like is then grown onto the capacitative contacts 27 by CVD, and then the capacitative contact pads 33 are formed by photolithography and dry etching.

Titanium nitride is then grown on the capacitative contact pads 33 so as to cover inner walls of cylindrical holes, thereby forming the capacitor lower electrodes 34.

The capacitative insulating film 35 is then formed in such a way as to cover the surfaces of the lower electrodes 34, after which the polysilicon upper electrode 36 and the tungsten upper electrode 38 are formed.

The second interlayer insulating film 39 is then formed on the tungsten upper electrode 38. The wiring lines 40 of aluminum or the like are also formed on the second interlayer insulating film 39. The surface protection film 41 is then formed, thereby forming the semiconductor device 100.

In this semiconductor device 100, the cap insulating film 17 with which the gap 41 has been filled functions as part of the gate insulating film, and therefore the effective gate insulating film thickness in the region in which GIDL influenced by the gate electric field occurs can be increased. This reduces the susceptibility of the device to the effects of the gate electric field, and therefore the GIDL in the depletion layer formed between the first impurity-diffused layer 19 and the semiconductor substrate 1 can be suppressed.

Therefore, if the semiconductor device 100 in the first mode of embodiment of the present invention is used as a DRAM, it is possible to suppress deterioration of the information retention characteristic attributable to GIDL influenced by the gate electric field. Moreover, by disposing the upper end surface 9a of the second conductive film 9 in a location that is higher than the surface of the semiconductor substrate 1, increases in the wiring resistance of the word lines 10 can also be suppressed.

### Second Mode of Embodiment

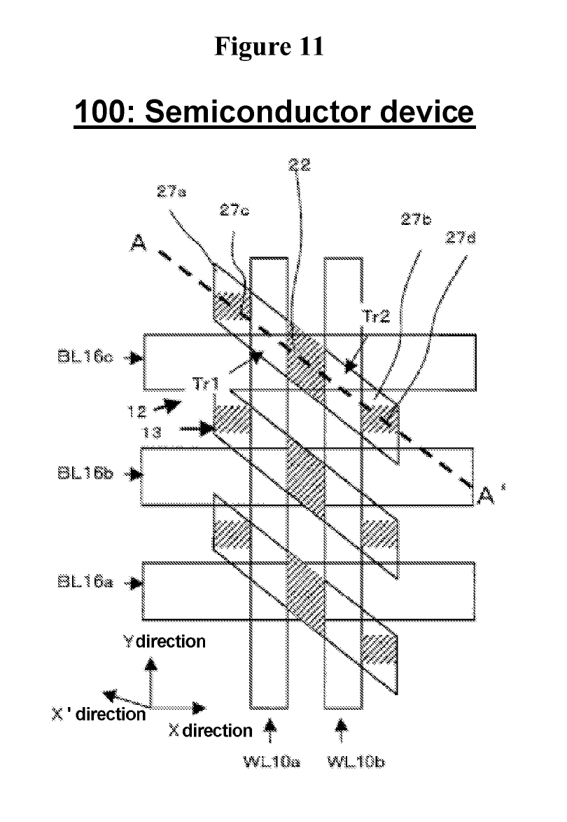

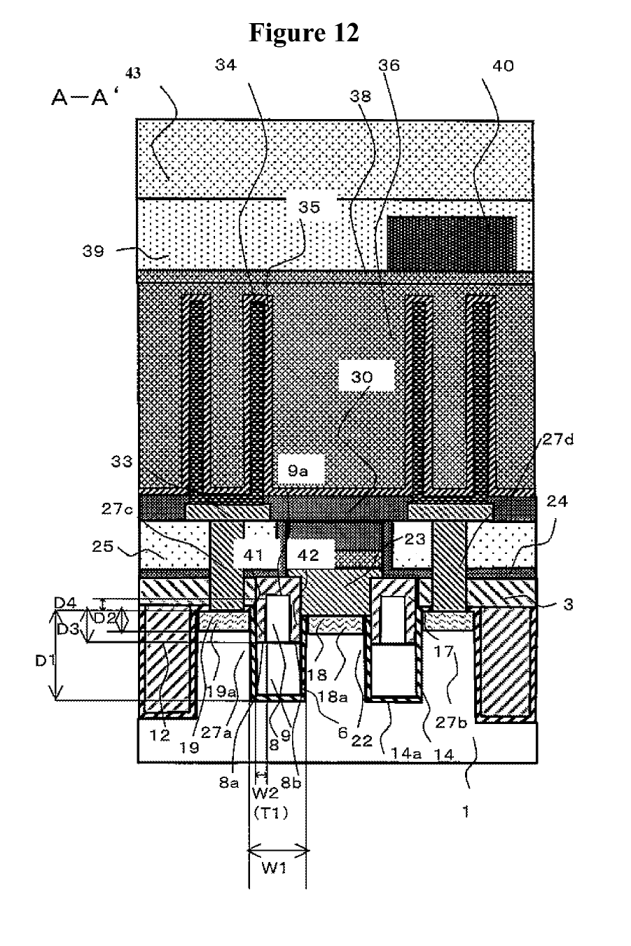

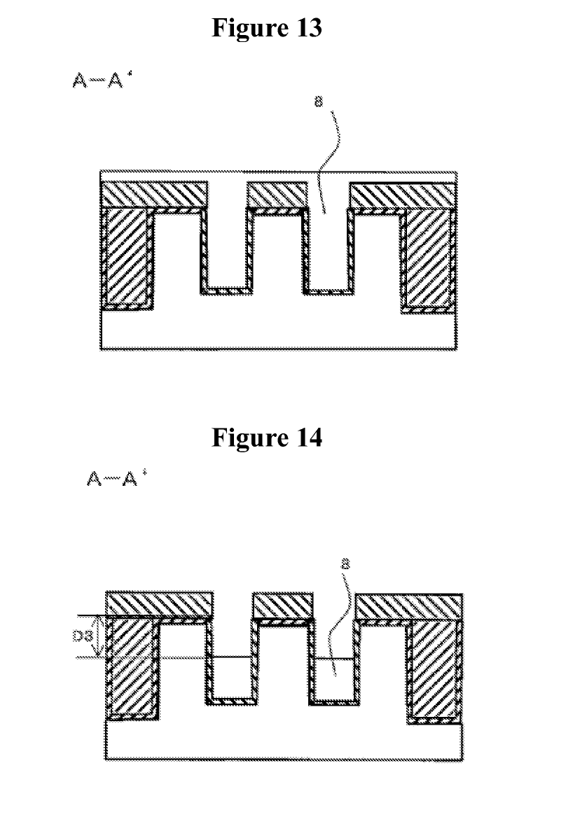

FIG. 11 to FIG. 18 are drawings illustrating the structure of a semiconductor device 100 according to a second preferred mode of embodiment of the present invention. The semiconductor device 100 according to this second mode of embodiment is a DRAM memory cell, FIG. 11 is a plan view, FIG. 12 is a cross-sectional view along A-A′ in FIG. 11, and FIG. 13 to FIG. 18 are a series of cross-sectional views in a manufacturing process.

The semiconductor device 100 in the second mode of embodiment will first be described with reference to the plan view in FIG. 11.

The semiconductor device 100 forms the memory cells of a DRAM. A plurality of element isolation regions 12 extending continuously in the X′-direction, and a plurality of active regions 13, also extending continuously in the X′-direction, are disposed alternately at equal intervals and with an equal pitch in the Y-direction on a semiconductor substrate 1. The element isolation regions 12 are formed by an element isolation insulating film which is embedded in a groove. A first embedded word line (hereinafter referred to as a first word line) WL10a and a second embedded word line (hereinafter referred to as a second word line) WL10b which extend continuously in the Y-direction are disposed straddling the plurality of element isolation regions 12 and the plurality of active regions 13.

The active regions 13 comprise a first capacitative contact region 27a, the first word line WL10a disposed adjacent to the first capacitative contact region 27a, a bit line contact region 22 disposed adjacent to the first word line WL10a, the second word line 10b disposed adjacent to the bit line contact region 22, and a second capacitative contact region 27b disposed adjacent to the second word line WL10b. The first capacitative contact region 27a, the first word line WL10a and the bit line (BL) contact region 22 form a first cell transistor Tr1, and the bit line contact region 22, the second word line WL10b and the second capacitative contact region 27c form a second cell transistor Tr2.

The memory cell in the second mode of embodiment of the present invention is formed by disposing a plurality of the abovementioned active regions 13 in the X-direction.

Next, with reference to FIG. 12, grooves 14 for word lines which also serve as the transistor gate electrodes are provided in the semiconductor substrate 1. The depth D1 of the grooves relative to the surface of the semiconductor substrate 1 can for example be set to 120 nm.

Gate insulating films 6 are provided in such a way as to cover the inner surfaces of the grooves 14 for the word lines. Word lines 10 are provided in the bottom portion of each groove, with the interposition of the gate insulating films 6.

Cap insulating films 17 are provided covering the word lines 10 and filling the grooves 14. Further, a first interlayer insulating film 3 is provided in such a way as to cover the semiconductor substrate 1. Semiconductor pillars located to the outside of the word lines 10 serve as the capacitative contact regions 27, and first impurity-diffused layers 19 which serve as either the source or the drain are provided on the upper surfaces of said semiconductor pillars. A semiconductor pillar located between the word lines 10 serves as the BL contact region 22, and a second impurity-diffused layer 18 which serves as the other of the source or the drain is provided on the upper surface of said semiconductor pillar. The first impurity-diffused layer 19, the gate insulating film 6, the word line WL10 and the second impurity-diffused layer 18 form the transistor Tr1.

Here, the depth of the first impurity-diffused layer 19 and the depth of the second impurity-diffused layer 18 from the surface of the semiconductor substrate 1 are the same, and this depth D2 can for example be set to 40 nm.

The word lines 10 also serve as the gate electrodes, and comprise a first conductive film 8 and a second conductive film 9. The first conductive film 8 is a film which is responsible for determining the threshold voltage of Tr1 and Tr2, and which also functions as a barrier film preventing heavy-metal atoms that are contained in the second conductive film 9 and that would adversely affect the characteristics of the transistor if dispersed in the semiconductor substrate 1, from reaching the gate insulating film 6.

If miniaturization progresses and the width W1 of the grooves 14 for the word lines decreases, it will become impossible for the second conductive films 9 to be embedded in the grooves 14 for the word lines in which the first conductive films 8 have been formed, as in the first mode of embodiment described hereinabove.

In this case, the first conductive films 8 completely fill the grooves 14 for the word lines, up to a depth of D3 from the surface of the semiconductor substrate 1. Relative to lower end surfaces 19a of the first impurity-diffused layers 19, the upper end surfaces 8a and 8b of the first conductive films 8 are disposed further toward a bottom surface 14a of the grooves 14 for the word lines. The depth D3 from the surface of the semiconductor substrate 1 to the upper end surfaces 8a of the first conductive films 8 can for example be set to 50 nm.

If a titanium nitride film is used as the first conductive film 8, its thickness can for example be set to 30 nm. The second conductive film 9 is formed on the first conductive film 8, and is provided in such a way as to fill part of the groove 14 for the word line, which has been filled by the first conductive film 8.

The second conductive film 9 protrudes from the upper end surfaces 8a and 8b of the first conductive film 8 in such a way that it faces portions of the first and second impurity-diffused layers 18 and 19. By this means, a gap 41 extending in the Y-direction and surrounded by the upper end surface 8a of the first conductive film 8, the second conductive film 9 and the gate insulating film 6 is formed above the upper end surface 8a of the first conductive film 8, and similarly a gap 42 extending in the Y-direction and surrounded by the upper end surface 8b of the first conductive film 8, the second conductive film 9 and the gate insulating film 6 is formed above the upper end surface 8b of the first conductive film 8.

The width of the gap 42 is equal to the width W2 of the gap 41, and the width of the gap 41 is equal to the width of a side wall 7. If the thickness of the first conductive film 8 is 5 nm, the width W2 of the gap 41 can be set to 5 nm.

The second conductive film 9 is a film intended to reduce the wiring resistance of the word lines 10, but because the first conductive film 8, which is a film functioning as a barrier film, is not present at the periphery of the second conductive film 9, the second conductive film 9 must also be a film that functions as a barrier film.

The upper end surface 9a of the second conductive film 9 is disposed between the surface of the semiconductor substrate 1 and the surface of the first interlayer insulating film 3. The height D4 to the upper end surface 9a of the second conductive film 9 relative to the surface of the semiconductor substrate 1 can for example be set to 5 nm. The wiring resistance of the word line 10 can be reduced by increasing the height to the upper end surface.

If a titanium nitride film is used as the second conductive film 9, its thickness can for example be set to 30 nm. The cap insulating films 17 are provided in such a way as to fill the gaps 41 and 42, but the gaps need not necessarily be completely filled.

Further, the cap insulating films 17 cover the second conductive films 9 which protrude from the surface of the semiconductor substrate 1, and the surfaces of the cap insulating films 17 are coplanar with the surface of the first interlayer insulating film 3. The thickness T1 of the cap insulating film 17 formed in the gap 41 is equal to the width W2 of the gap 41.

A bit line (BL) 23 connected to the impurity-diffused layer 18 in the BL contact region 22 is provided on the first interlayer insulating film 3. A cover insulating film is provided on the upper surface of the BL 23. A liner insulating film 24 is provided over the entire surface in such a way as to cover the sidewalls of the BL 23. SOD films 25 which fill recessed spaces formed between adjacent BLs are provided on the liner insulating film 24.

Capacitative contact holes 27 are provided penetrating through the SOD films 25 and the liner film 24. Capacitative contact plugs 27c and 27d are connected to the capacitative contact regions 27a and 27b respectively by way of the capacitative contact holes 27. Capacitative contact pads 33 are connected to the upper portions of the capacitative contact plugs 27c and 27d. Capacitor lower electrodes 34 are provided on the capacitative contact pads 33. Further, a capacitative insulating film 35 is provided covering the inner surfaces of the lower electrodes 34, and an upper polysilicon electrode 36 and an upper tungsten electrode 38 are provided on the capacitative insulating film 35, thereby forming a capacitor.

A second interlayer insulating film 39 is then formed on the tungsten upper electrode 38. Wiring lines 40 of aluminum or the like are also formed on the second interlayer insulating film 39. A surface protection film 41 is then formed, thereby forming the semiconductor device 100.

In the semiconductor device 100, the cap insulating film 17 is provided in the groove 14 for the word lines in such a way as to cover the second conductive film 9 which protrudes from the upper end surface 8a and the upper end surface 8b of the first conductive film 8, and the upper end surface 9a of which is located higher than the surface of the semiconductor substrate 1, and thus the cap insulating film 17 functions as part of the gate insulating film 6 located on the upper end surface 8a of the first conductive film 8, and therefore the gate insulating film thickness in the region in which GIDL (Gate-Induced Drain Leakage) occurs can be increased, the junction field of the transistor can be reduced, and the refresh characteristics can be improved. Moreover, by setting the location of the upper end surface 9a of the second conductive film 9 to a location that is higher than the surface of the semiconductor substrate 1, the wiring resistance of the second conductive film 9 can be maintained.

A method of manufacturing the semiconductor device illustrated in FIG. 11 and FIG. 12 will now be described with reference to FIG. 13 to FIG. 18. FIG. 13 to FIG. 18 are cross-sectional views along A-A′ in FIG. 11. Processes prior to this are the same as in FIG. 3 to FIG. 5 in the first mode of embodiment.

First, as in the first mode of embodiment described hereinabove, a pad oxide film 2 is formed on the semiconductor substrate 1, and the element isolation regions 12, filled using an insulating film comprising a silicon dioxide film, are formed using a known STI method, as illustrated in FIG. 3.

Next, as illustrated in FIG. 4, the first interlayer insulating film 3 is formed on the pad oxide film 2 using a silicon dioxide film, for example. Next, as illustrated in FIG. 5, the semiconductor substrate 1 is etched by dry etching using the first interlayer insulating film 3 as a mask to form the grooves 14 for the word lines. The depth D1 of the grooves 14 for the word lines can for example be set to 120 nm. Further, the width W1 of the grooves 14 for the word lines can for example be set to 50 nm.

Then the gate insulating film 6 which is a constituent of an n-type transistor is formed on the active region 13 of the silicon substrate 1 using a thermal oxidation process.

Next, as illustrated in FIG. 13, the first conductive film 8 comprising titanium nitride or the like is deposited by CVD to a thickness of 30 nm in such a way as to cover the surfaces of the gate insulating film 6 and the first interlayer insulating film 3.

Next, as illustrated in FIG. 14, the first conductive films 8 are etched back in such a way that, relative to the lower end portions of the first impurity-diffused layers 19 and the second impurity-diffused layer 18, the locations of the upper end surfaces 8a and 8b of the first conductive films 8 are disposed further toward the bottom surface 14a of the grooves 14 for the word lines.

Here, the depth D3 of the upper end surfaces 8a and 8b of the first conductive films 8 relative to the surface of the semiconductor substrate 1 can for example be set to 50 nm.

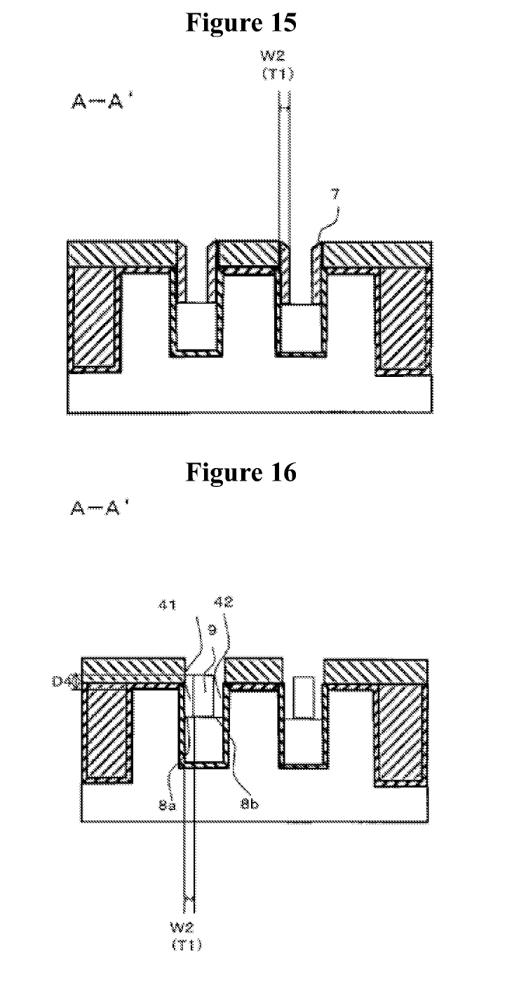

Next, as illustrated in FIG. 15, a silicon nitride film or the like is deposited by CVD and is etched back to form the side walls 7 inside the grooves 14 for the word lines. The width W2 of the side walls 7 can for example be set to 5 nm.

Next, as illustrated in FIG. 16, the second conductive film 9 comprising tungsten or the like is deposited by CVD onto the surface of the first conductive films 8 to a thickness of 30 nm in such a way as to fill the grooves 14 for the word lines.

The second conductive film 9 is then etched back to a location that is higher than the surface of the semiconductor substrate 1 and is lower than the surface of the first interlayer insulating film 3. The side walls 7 are also removed. Here, the height D4 of the second conductive film 9 from the semiconductor substrate can for example be set to 5 nm.

By this means, the gap 41 surrounded by the upper end portion 8a of the first conductive film 8, the second conductive film 9 and the gate insulating film 6 is formed above the upper end portion 8a of the first conductive film 8, and the gap 42 surrounded by the upper end portion 8b of the first conductive film 8, the second conductive film 9 and the gate insulating film 6 is formed above the upper end portion 8b of the first conductive film 8.

The width W2 of the gap 41 is equal to the width W2 of the side walls 7, and can for example be set to 5 nm. The width of the gap 42 is equal to W2.

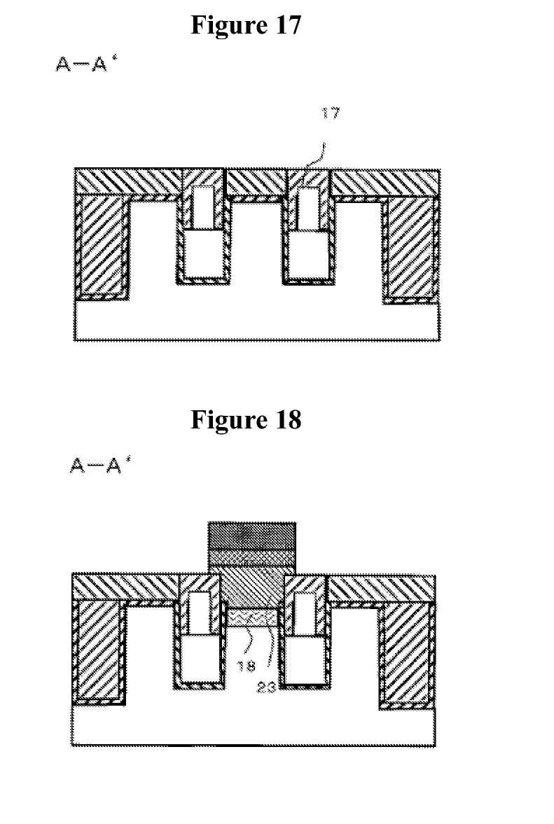

Next, as illustrated in FIG. 17, the cap insulating films 17 (for example silicon nitride films having a thickness of 50 nm) are deposited in such a way as to fill the gaps 41 and 42, after which the cap insulating films 17 are etched back such that they become flush with the surface of the first interlayer insulating film 3. The thickness T1 of the cap insulating film formed in the gaps 41 and 42 is equal to the width W2 of the side walls. T1 can for example be set to 5 nm.

By filling the gap 41 using the cap insulating film 17 in this way, the cap insulating film 17 with which the gap 41 has been filled functions as part of the gate insulating film 17, and therefore the effective gate insulating film 17 thickness in the region in which GIDL influenced by the gate electric field occurs can be increased. This reduces the susceptibility of the device to the effects of the gate electric field, and therefore the GIDL in the depletion layer formed between the first impurity-diffused layer 19 and the semiconductor substrate 1 can be suppressed.

Therefore, if the semiconductor device 100 in the second mode of embodiment of the present invention is used as a DRAM, it is possible to suppress deterioration of the information retention characteristic attributable to GIDL influenced by the gate electric field.

Moreover, by disposing the upper end surface 9a of the second conductive film 9 in a location that is higher than the surface of the semiconductor substrate 1, increases in the wiring resistance of the word lines 10 can also be suppressed.

Next, as illustrated in FIG. 18, a portion of the first interlayer insulating film 3 is removed by photolithography and dry etching, to form a bit contact connected to the upper surface of the bit contact region 22. The bit contact is formed as an open pattern in the shape of a line extending in the same direction (the Y-direction in FIG. 1) as the word lines 10. The surface of the semiconductor substrate 1 is exposed in the areas in which the bit contact pattern and the active regions intersect.

After the bit contact has been formed, an n-type impurity (arsenic or the like) is ion-implanted to form the second impurity-diffused layer 18 in the vicinity of the surface of the silicon. The second impurity-diffused region which has been formed functions as the source region or the drain region of the transistor. A laminated film comprising a polysilicon film, a tungsten film and a silicon nitride film, for example, is then formed by CVD. This is then patterned into the shape of a line by photolithography and dry etching to form the bit line 23. The bit line 23 is formed as a pattern extending in a direction (the X-direction in FIG. 1) that intersects the word lines 10. The polysilicon film which forms the lower layer of the bit line 23 is connected to the second impurity-diffused layer 18 in the sections of the silicon surface that are exposed within the bit contact.

Next, as illustrated in FIG. 12, a silicon nitride film is formed covering the side surfaces of the bit line 23, after which the liner film 24 covering the upper surface thereof is formed using a silicon nitride film, for example, by CVD or the like.

The SOD films 25, which are coating films, are deposited in such a way as to fill the spaces between the bit lines, after which an annealing process is performed in a high-temperature steam (H₂O) atmosphere to reform the SOD films to a solid film. Planarization is performed by CMP until the upper surface of the liner film 24 is exposed.

The capacitative contacts 27 are then formed by employing photolithography and dry etching to penetrate through the SOD films 25 and the liner film 24. Further, an n-type impurity (arsenic or the like) is ion-implanted in the vicinity of the surface in the capacitative contact regions 27a and 28b to form the first impurity-diffused layers 19 in the vicinity of the surface of the silicon. The first impurity-diffused regions 19 which have been formed function as the source region or the drain region of the transistor.

Next, the insides of the capacitative contacts 27 are filled using tungsten or the like to form the capacitative contact plugs 27c and 27d.

A wiring-line material layer comprising titanium nitride, tungsten or the like is then grown onto the capacitative contacts 27 by CVD, and then the capacitative contact pads 33 are formed by photolithography and dry etching.

Titanium nitride is then grown on the capacitative contact pads 33 so as to cover inner walls of cylindrical holes, thereby forming the capacitor lower electrodes 34.

The capacitative insulating film 35 is then formed in such a way as to cover the surfaces of the lower electrodes 34, after which the polysilicon upper electrode 36 and the tungsten upper electrode 38 are formed.

The second interlayer insulating film 39 is then formed on the tungsten upper electrode 38. Wiring lines 40 of aluminum or the like are also formed on the second interlayer insulating film 39. A surface protection film 41 is then formed, thereby forming the semiconductor device 100.

In this semiconductor device 100, the cap insulating film 17 with which the gap 41 has been filled functions as part of the gate insulating film 17, and therefore the effective gate insulating film thickness in the region in which GIDL influenced by the gate electric field occurs can be increased. This reduces the susceptibility of the device to the effects of the gate electric field, and therefore the GIDL in the depletion layer formed between the first impurity-diffused layer 19 and the semiconductor substrate 1 can be suppressed.

Therefore, if the semiconductor device 100 in the second mode of embodiment of the present invention is used as a DRAM, it is possible to suppress deterioration of the information retention characteristic attributable to GIDL influenced by the gate electric field. Moreover, by disposing the upper end surface 9a of the second conductive film 9 in a location that is higher than the surface of the semiconductor substrate 1, increases in the wiring resistance of the word lines 10 can also be suppressed.

### Third Mode of Embodiment

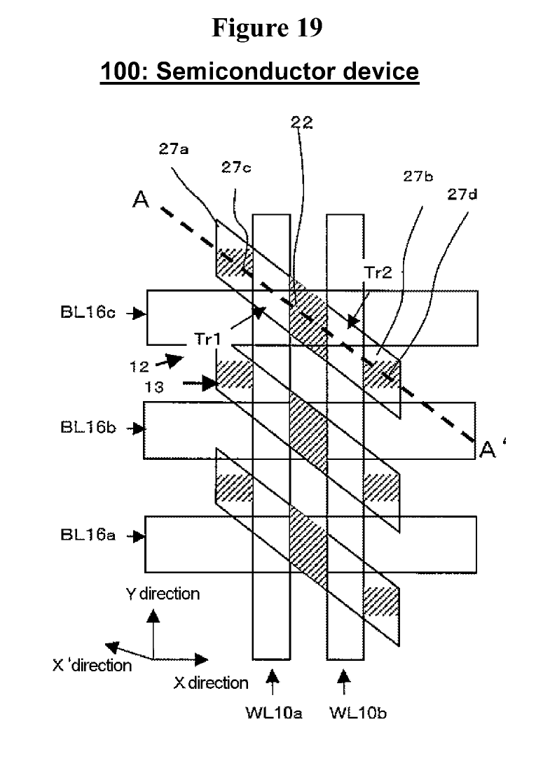

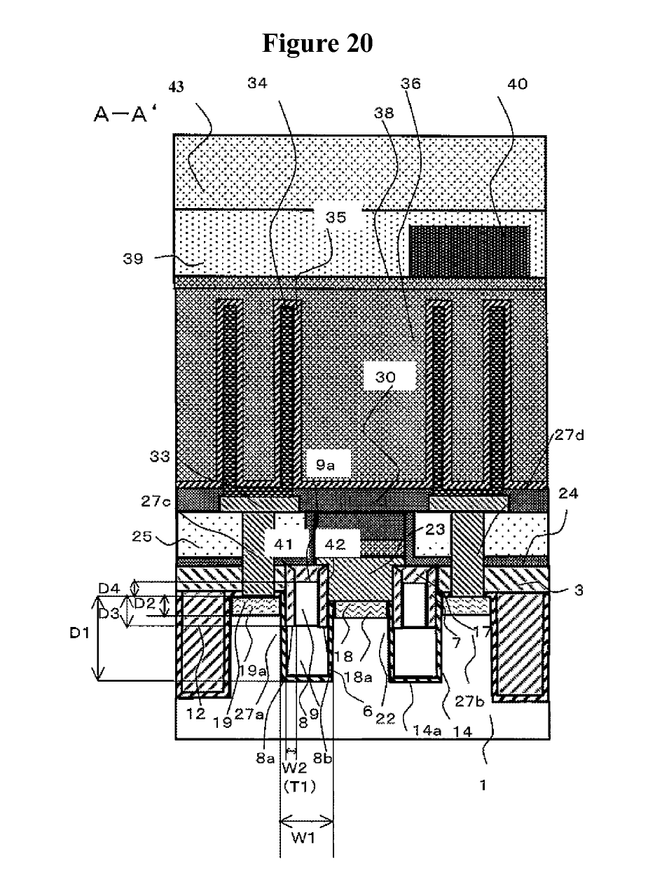

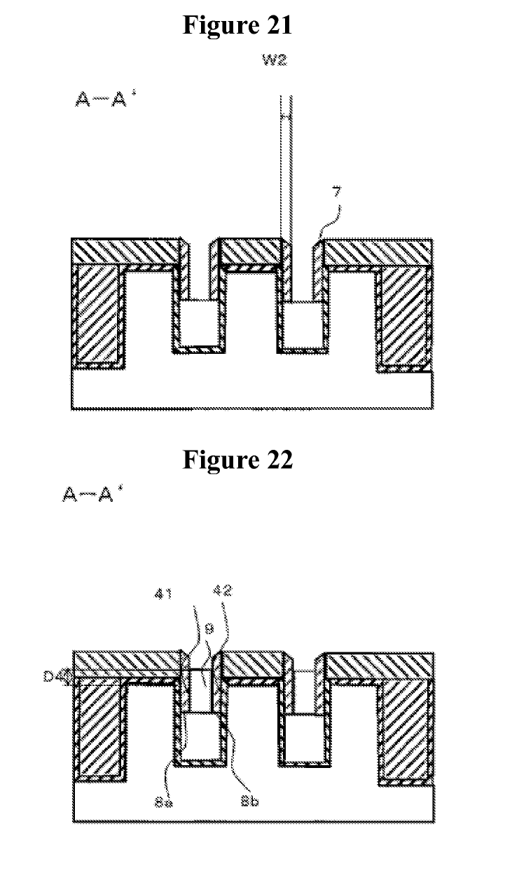

FIG. 19 to FIG. 24 are drawings illustrating the structure of a semiconductor device 100 according to a third preferred mode of embodiment of the present invention. The semiconductor device 100 according to the third mode of embodiment is a DRAM memory cell, FIG. 19 is a plan view, FIG. 20 is a cross-sectional view along A-A′ in FIG. 20, and FIG. 21 to FIG. 24 are a series of cross-sectional views in a manufacturing process.

The semiconductor device 100 in the third mode of embodiment will first be described with reference to the plan view in FIG. 19.

The semiconductor device 100 forms the memory cells of a DRAM. A plurality of element isolation regions 12 extending continuously in the X′-direction, and a plurality of active regions 13, also extending continuously in the X′-direction, are disposed alternately at equal intervals and with an equal pitch in the Y-direction on a semiconductor substrate 1. The element isolation regions 12 are formed by an element isolation insulating film which is embedded in a groove. A first embedded word line (hereinafter referred to as a first word line) WL10a and a second embedded word line (hereinafter referred to as a second word line) WL10b which extend continuously in the Y-direction are disposed straddling the plurality of element isolation regions 12 and the plurality of active regions 13.

The active regions 13 comprise a first capacitative contact region 27a, the first word line WL10a disposed adjacent to the first capacitative contact region 27a, a bit line contact region 22 disposed adjacent to the first word line WL10a, the second word line 10b disposed adjacent to the bit line contact region 22, and a second capacitative contact region 27b disposed adjacent to the second word line WL10b. The first capacitative contact region 27a, the first word line WL10a and the bit line contact region 22 form a first cell transistor Tr1, and the bit line contact region 22, the second word line WL10b and the second capacitative contact region 27c form a second cell transistor Tr2.

The memory cell in the third mode of embodiment of the present invention is formed by disposing a plurality of the abovementioned active regions 13 in the X-direction.

Next, with reference to FIG. 20, grooves 14 for word lines which also serve as the transistor gate electrodes are provided in the semiconductor substrate 1. The depth D1 of the grooves relative to the surface of the semiconductor substrate 1 can for example be set to 120 nm.

Gate insulating films 6 are provided in such a way as to cover the inner surfaces of the grooves 14 for the word lines. Word lines 10 are provided in the bottom portion of each groove, with the interposition of the gate insulating films 6.

Side walls 7 and cap insulating films 17 are provided covering the word lines 10 and filling the grooves 14. Further, a first interlayer insulating film 3 is provided in such a way as to cover the semiconductor substrate 1. Semiconductor pillars located to the outside of the word lines 10 serve as the capacitative contact regions 27, and first impurity-diffused layers 19 which serve as either the source or the drain are provided on the upper surfaces of said semiconductor pillars. A semiconductor pillar located between the word lines 10 serves as the BL contact region 22, and a second impurity-diffused layer 18 which serves as the other of the source or the drain is provided on the upper surface of said semiconductor pillar. The first impurity-diffused layer 19, the gate insulating film 6, the word line WL10 and the second impurity-diffused layer 18 form the transistor Tr1.

Here, the depth of the first impurity-diffused layer 19 and the depth of the second impurity-diffused layer 18 from the surface of the semiconductor substrate 1 are the same, and this depth D2 can for example be set to 40 nm.

The word lines 10 also serve as the gate electrodes, and comprise a first conductive film 8 and a second conductive film 9. The first conductive film 8 is a film which is responsible for determining the threshold voltage of Tr1 and Tr2, and which also functions as a barrier film preventing heavy-metal atoms that are contained in the second conductive film 9 and that would adversely affect the characteristics of the transistor if dispersed in the semiconductor substrate 1, from reaching the gate insulating film 6.

If miniaturization progresses and the width W1 of the grooves 14 for the word lines decreases, it will become impossible for the second conductive films 9 to be embedded in the grooves 14 for the word lines in which the first conductive films 8 have been formed, as in the first mode of embodiment described hereinabove.

In this case, the first conductive films 8 completely fill the grooves 14 for the word lines, up to a depth of D3 from the surface of the semiconductor substrate 1. Relative to lower end surfaces 19a of the first impurity-diffused layers 19, the upper end surfaces 8a and 8b of the first conductive films 8 are disposed further toward a bottom surface 14a of the grooves 14 for the word lines. The depth D3 from the surface of the semiconductor substrate 1 to the upper end surfaces 8a of the first conductive films 8 can for example be set to 50 nm.

If a titanium nitride film is used as the first conductive film 8, its thickness can for example be set to 30 nm. The side walls 7 are situated on the first conductive films 8, on the surface of the gate insulating films 6 inside the grooves 14 for the word lines.

The second conductive films 9 are formed on the first conductive films 8, and are provided on the surfaces of the side walls 7 on the sidewalls of the grooves 14 for the word lines, in such a way as to fill the grooves 14 for the word lines.

The second conductive film 9 protrudes from the upper end surfaces 8a and 8b of the first conductive film 8 in such a way that it faces portions of the first and second impurity-diffused layers 18 and 19.

By this means, the side wall 7 extending in the Y-direction in the region surrounded by the upper end surface 8a of the first conductive film 8, the second conductive film 9 and the gate insulating film 6 is disposed on the upper end surface 8a of the first conductive film 8, and similarly the side wall 7 extending in the Y-direction in the region surrounded by the upper end surface 8b of the first conductive film 8, the second conductive film 9 and the gate insulating film 6 is disposed on the upper end surface 8b of the first conductive film 8. The width W2 of the side walls 7 can be set to 5 nm.

The second conductive film 9 is a film intended to reduce the wiring resistance of the word lines 10, but because the first conductive film 8, which is a film functioning as a barrier film, is not present at the periphery of the second conductive film 9, the second conductive film 9 must also be a film that functions as a barrier film.

The upper end surface 9a of the second conductive film 9 is disposed between the surface of the semiconductor substrate 1 and the surface of the first interlayer insulating film 3. The height D4 to the upper end surface 9a of the second conductive film 9 relative to the surface of the semiconductor substrate 1 can for example be set to 5 nm. The wiring resistance of the word line 10 can be reduced by increasing the height to the upper end surface.

If a titanium nitride film is used as the second conductive film 9, its thickness can for example be set to 30 nm. The cap insulating films 17 are provided in such a way as to embed the side walls 7 and the second conductive films 9.

Further, the cap insulating films 17 cover the second conductive films 9 which protrude from the surface of the semiconductor substrate 1, and the surfaces of the cap insulating films 17 are coplanar with the surface of the first interlayer insulating film 3.

A bit line (BL) 23 connected to the impurity-diffused layer 18 in the BL contact region 22 is provided on the first interlayer insulating film 3. A cover insulating film is provided on the upper surface of the BL 23. A liner insulating film 24 is provided over the entire surface in such a way as to cover the sidewalls of the BL 23. SOD films 25 which fill recessed spaces formed between adjacent BLs are provided on the liner insulating film 24.

Capacitative contact holes 27 are provided penetrating through the SOD films 25 and the liner film 24. Capacitative contact plugs 27c and 27d are connected to the capacitative contact regions 27a and 27b respectively by way of the capacitative contact holes 27. Capacitative contact pads 33 are connected to the upper portions of the capacitative contact plugs 27c and 27d. Capacitor lower electrodes 34 are provided on the capacitative contact pads 33. Further, a capacitative insulating film 35 is provided covering the inner surfaces of the lower electrodes 34, and an upper polysilicon electrode 36 and an upper tungsten electrode 38 are provided on the capacitative insulating film 35, thereby forming a capacitor.

A second interlayer insulating film 39 is then formed on the tungsten upper electrode 38. Wiring lines 40 of aluminum or the like are also formed on the second interlayer insulating film 39. A surface protection film 41 is then formed, thereby forming the semiconductor device 100.

In the semiconductor device 100, the side walls 7 and the cap insulating film 17 are provided in the groove 14 for the word lines in such a way as to cover the second conductive film 9 which protrudes from the upper end surface 8a and the upper end surface 8b of the first conductive film 8, and the upper end surface 9a of which is located higher than the surface of the semiconductor substrate 1, and thus the side walls 7 and the cap insulating film 17 function as part of the gate insulating film 6 located on the upper end surface 8a of the first conductive film 8, and therefore the gate insulating film thickness in the region in which GIDL (Gate-Induced Drain Leakage) occurs can be increased, the junction field of the transistor can be reduced, and the refresh characteristics can be improved. Moreover, by setting the location of the upper end surface 9a of the second conductive film 9 to a location that is higher than the surface of the semiconductor substrate 1, the wiring resistance of the second conductive film 9 can be maintained.

A method of manufacturing the semiconductor device illustrated in FIG. 19 and FIG. 20 will now be described with reference to FIG. 21 to FIG. 24. FIG. 21 to FIG. 24 are cross-sectional views along A-A′ in FIG. 19.

Processes prior to this are the same as in FIG. 3 to FIG. 5 in the first mode of embodiment and FIG. 13 and FIG. 14 in the second mode of embodiment.

First, as in the first mode of embodiment, a pad oxide film 2 is formed on the semiconductor substrate 1, and the element isolation regions 12, filled using an insulating film comprising a silicon dioxide film, are formed using a known STI method, as illustrated in FIG. 3.

Next, as illustrated in FIG. 4, the first interlayer insulating film 3 is formed on the pad oxide film 2 using a silicon dioxide film, for example.

Next, as illustrated in FIG. 5, the semiconductor substrate 1 is etched by dry etching using the first interlayer insulating film 3 as a mask to form the grooves 14 for the word lines.

The depth D1 of the grooves 14 for the word lines can for example be set to 120 nm. Further, the width W1 of the grooves 14 for the word lines can for example be set to 50 nm.

Then the gate insulating film 6 which is a constituent of an n-type transistor is formed on the active region 13 of the silicon substrate 1 using a thermal oxidation process.

Next, in the same way as in the second mode of embodiment, as illustrated in FIG. 13, the first conductive film 8 comprising titanium nitride or the like is deposited by CVD to a thickness of 30 nm in such a way as to cover the surfaces of the gate insulating film 6 and the first interlayer insulating film 3.

Next, as illustrated in FIG. 14, the first conductive films 8 are etched back in such a way that, relative to the lower end portions of the first impurity-diffused layers 19 and the second impurity-diffused layer 18, the locations of the upper end surfaces 8a and 8b of the first conductive films 8 are disposed further toward the bottom surface 14a of the grooves 14 for the word lines.

Here, the depth D3 of the upper end surfaces 8a and 8b of the first conductive films 8 relative to the surface of the semiconductor substrate 1 can for example be set to 50 nm.

Next, as illustrated in FIG. 21, a silicon nitride film or the like is deposited by CVD and is etched back to form the side walls 7 inside the grooves 14 for the word lines. The width W2 of the side walls 7 can for example be set to 5 nm.

Next, as illustrated in FIG. 22, the second conductive film 9 comprising tungsten or the like is deposited by CVD onto the surfaces of the first conductive films 8 and the side walls 7 to a thickness of 30 nm in such a way as to fill the grooves 14 for the word lines.

The second conductive film 9 is then etched back to a location that is higher than the surface of the semiconductor substrate 1 and is lower than the surface of the first interlayer insulating film 3.

Here, the height D4 of the second conductive film 9 from the semiconductor substrate can for example be set to 5 nm.

By this means, a region 41 filled by the side wall 7 and surrounded by the upper end portion 8a of the first conductive film 8, the second conductive film 9 and the gate insulating film 6 is formed above the upper end portion 8a of the first conductive film 8, and similarly a region 42 filled by the side wall 7 and surrounded by the upper end portion 8b of the first conductive film 8, the second conductive film 9 and the gate insulating film 6 is formed above the upper end portion 8b of the first conductive film 8. The width W2 of the region 41 filled by the side wall 7 can for example be set to 5 nm.

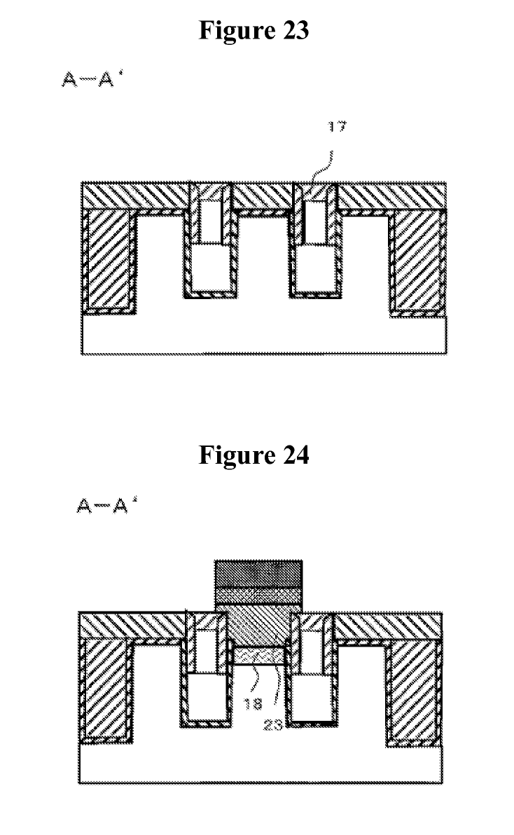

Next, as illustrated in FIG. 23, the cap insulating films 17 (for example silicon nitride films having a thickness of 50 nm) are deposited on the surfaces of the second conductive films 9 and the side walls 7 in such a way as to fill the grooves 14 for the word lines, after which the cap insulating films 17 are etched back such that they become flush with the surface of the first interlayer insulating film 3. By filling the section 41 surrounded by the upper end portions 8a of the first conductive films 8, the second conductive films 9 and the gate insulating films 6 using the side walls 7 and the cap insulating films 17 in this way, the side walls 7 and the cap insulating film 17 with which this section 41 has been filled function as part of the gate insulating film 6, and therefore the effective gate insulating film thickness in the region in which GIDL influenced by the gate electric field occurs can be increased. This reduces the susceptibility of the device to the effects of the gate electric field, and therefore the GIDL in the depletion layer formed between the first impurity-diffused layer 19 and the semiconductor substrate 1 can be suppressed.

Therefore, if the semiconductor device 100 in the third mode of embodiment of the present invention is used as a DRAM, it is possible to suppress deterioration of the information retention characteristic attributable to GIDL influenced by the gate electric field. Moreover, by disposing the upper end surface 9a of the second conductive film 9 in a location that is higher than the surface of the semiconductor substrate 1, increases in the wiring resistance of the word lines 10 can also be suppressed.

Next, as illustrated in FIG. 24, a portion of the first interlayer insulating film 3 is removed by photolithography and dry etching, to form a bit contact connected to the upper surface of the bit contact region 22. The bit contact is formed as an open pattern in the shape of a line extending in the same direction (the Y-direction in FIG. 1) as the word lines 10.

The surface of the semiconductor substrate 1 is exposed in the areas in which the bit contact pattern and the active regions intersect. After the bit contact has been formed, an n-type impurity (arsenic or the like) is ion-implanted to form the second impurity-diffused layer 18 in the vicinity of the surface of the silicon. The second impurity-diffused region 18 which has been formed functions as the source region or the drain region of the transistor.

A laminated film comprising a polysilicon film, a tungsten film and a silicon nitride film, for example, is then formed by CVD. This is then patterned into the shape of a line by photolithography and dry etching to form the bit line 23. The bit line 23 is formed as a pattern extending in a direction (the X-direction in FIG. 1) that intersects the word lines 10. The polysilicon film which forms the lower layer of the bit line is connected to the second impurity-diffused layer 18 in the sections of the silicon surface that are exposed within the bit contact.

Next, as illustrated in FIG. 20, a silicon nitride film is formed covering the side surfaces of the bit line 23, after which the liner film 24 covering the upper surface thereof is formed using a silicon nitride film, for example, by CVD or the like.

The SOD films 25, which are coating films, are deposited in such a way as to fill the spaces between the bit lines, after which an annealing process is performed in a high-temperature steam (H₂O) atmosphere to reform the SOD films to a solid film. Planarization is performed by CMP until the upper surface of the liner film 24 is exposed.

The capacitative contacts 27 are then formed by employing photolithography and dry etching to penetrate through the SOD films 25 and the liner film 24. Further, an n-type impurity (arsenic or the like) is ion-implanted in the vicinity of the surface in the capacitative contact regions 27a and 27b to form the first impurity-diffused layers 19 in the vicinity of the surface of the silicon. The first impurity-diffused regions 19 which have been formed function as the source region or the drain region of the transistor.

Next, the insides of the capacitative contacts 27 are filled using tungsten or the like to form the capacitative contact plugs 27c and 27d.

A wiring-line material layer comprising titanium nitride, tungsten or the like is then grown onto the capacitative contacts 27 by CVD, and then the capacitative contact pads 33 are formed by photolithography and dry etching.

Titanium nitride is then grown on the capacitative contact pads 33 so as to cover inner walls of cylindrical holes, thereby forming the capacitor lower electrodes 34.

The capacitative insulating film 35 is then formed in such a way as to cover the surfaces of the lower electrodes 34, after which the polysilicon upper electrode 36 and the tungsten upper electrode 38 are formed.

The second interlayer insulating film 39 is then formed on the tungsten upper electrode 38. The wiring lines 40 of aluminum or the like are also formed on the second interlayer insulating film 39. A surface protection film 41 is then formed, thereby forming the semiconductor device 100.

In this semiconductor device 100, the side walls 7 and the cap insulating films 17, with which the sections 41 surrounded by the upper end portions 8a of the first conductive films 8, the second conductive films 9 and the gate insulating films 6 have been filled, function as part of the gate insulating film 6, and therefore the effective gate insulating film thickness in the region in which GIDL influenced by the gate electric field occurs can be increased. This reduces the susceptibility of the device to the effects of the gate electric field, and therefore the GIDL in the depletion layer formed between the first impurity-diffused layer 19 and the semiconductor substrate 1 can be suppressed.

Therefore, if the semiconductor device 100 in the third mode of embodiment of the present invention is used as a DRAM, it is possible to suppress deterioration of the information retention characteristic attributable to GIDL influenced by the gate electric field. Moreover, by disposing the upper end surface 9a of the second conductive film 9 in a location that is higher than the surface of the semiconductor substrate 1, increases in the wiring resistance of the word lines 10 can also be suppressed.

Preferred modes of embodiment of the present invention have been described hereinabove, but various modifications to the present invention may be made without deviating from the gist of the present invention, without limitation to the abovementioned modes of embodiment, and it goes without saying that these are also included within the scope of the present invention.

This application is based upon Japanese Patent Application No. 2012-212802, filed on Sep. 26, 2012, the entire disclosure of which is incorporated into this application by reference.

### EXPLANATION OF THE REFERENCE NUMBERS

1 Semiconductor substrate
2 Pad oxide film
3 First interlayer insulating film
6 Gate insulating film
7 Side wall
8 First conductive film
9 Second conductive film
10 Word line
10a First word line
10b Second word line
12 Element isolation region
13 Active region
14 Groove
17 Cap insulating film
18 Second impurity-diffused layer
19 First impurity-diffused layer
22 Bit line contact region
23 Bit line
24 Liner insulating film
25 SOD film
27a First capacitative contact region
27b Second capacitative contact region
33 Capacitative contact pad
34 Capacitor lower electrode
35 Capacitative insulating film
36 Upper polysilicon electrode
38 Upper tungsten electrode
39 Second interlayer insulating film
40 Wiring line
41 Gap
42 Gap
100 Semiconductor device

1. A semiconductor device comprising:
a groove provided in a semiconductor substrate;
a gate insulating film provided in such a way as to cover the inner surfaces of the groove;
inside the groove, a first conductive film, of which a first upper end surface is provided in a location that is lower than the surface of the semiconductor substrate;
inside the groove, a second conductive film which protrudes from the first upper end surface, and of which a second upper end surface is provided in a location that is higher than the surface of the semiconductor substrate; and
a cap insulating film provided in the groove in such a way as to cover the protruding portion of the second conductive film that protrudes from the first upper end surface.

2. The semiconductor device of claim 1, wherein the cap insulating film functions as part of the gate insulating film located on the first upper end surface.

3. The semiconductor device of claim 2, wherein the effective thickness of the gate insulating film in a region in which GIDL occurs is increased by causing the cap insulating film to function as part of the gate insulating film.

4. The semiconductor device of claim 1, wherein increases in the wiring resistance of the second conductive film are suppressed by providing the second upper end surface in a location that is higher than the surface of the semiconductor substrate.

5. The semiconductor device of claim 1, wherein the first conductive film and the second conductive film form a gate electrode.

6. The semiconductor device of claim 1, wherein an impurity-diffused layer is provided in such a way as to be adjacent to the groove, and the first upper end surface is provided in a location that is lower than a lower end surface of the impurity-diffused layer.

7. The semiconductor device of claim 1, wherein an interlayer insulating film is provided in such a way as to cover the semiconductor substrate, and the second upper end surface is disposed in a location that is higher than the surface of the semiconductor substrate and lower than the surface of the interlayer insulating film.

8. The semiconductor device of claim 1, wherein the first conductive film is provided at the periphery of the second conductive film, and the first conductive film functions as a barrier film preventing heavy-metal atoms contained in the second conductive film from reaching the gate insulating film.

9. The semiconductor device of claim 1, wherein the first conductive film is provided on an upper portion of the second conductive film, and the second conductive film itself functions as a barrier film preventing heavy-metal atoms contained in the second conductive film from reaching the gate insulating film.

10. The semiconductor device of claim 9, wherein side walls are provided on an upper portion of the first conductive film, on surfaces of the gate insulating film on the inner walls of the groove, the second conductive film is provided in such a way as to be surrounded by the side walls, and the side walls function, in conjunction with the cap insulating film, as part of the gate insulating film.

11. A method of manufacturing a semiconductor device, comprising:
etching a semiconductor substrate to form a groove in the semiconductor substrate;
forming a gate insulating film in such a way as to cover the inner surfaces of the groove;
forming a first conductive film inside the groove in such a way that a first upper end surface of said first conductive film is disposed in a location that is lower than the surface of the semiconductor substrate;
forming a second conductive film inside the groove in such a way that it protrudes from the first upper end surface, and in such a way that a second upper end surface of said second conductive film is disposed in a location that is higher than the surface of the semiconductor substrate; and
forming a cap insulating film in the groove in such a way as to cover the protruding portion of the second conductive film that protrudes from the first upper end surface.

12. The method of claim 11, wherein the cap insulating film functions as part of the gate insulating film located on the first upper end surface.

13. The method of claim 12, wherein the effective thickness of the gate insulating film in a region in which GIDL occurs is increased by causing the cap insulating film to function as part of the gate insulating film.

14. The method of claim 11, wherein the first conductive film is formed at the periphery of the second conductive film, and the first conductive film functions as a barrier film preventing heavy-metal atoms contained in the second conductive film from reaching the gate insulating film.

15. The method of claim 11, wherein the first conductive film is formed on an upper portion of the second conductive film, and the second conductive film itself functions as a barrier film preventing heavy-metal atoms contained in the second conductive film from reaching the gate insulating film.

16. The method of claim 15, wherein side walls are additionally formed on an upper portion of the first conductive film, on surfaces of the gate insulating film on the inner walls of the groove, the second conductive film is formed in such a way as to be surrounded by the side walls, and the side walls function, in conjunction with the cap insulating film, as part of the gate insulating film.
